(19) United States
(12) Patent Application Publication
(10) Pub. No.: US 2026/0155330 A1
(43) Pub. Date: Jun. 4, 2026

(54) GAS CLUSTER ION BEAM APPARATUS

(71) Applicant: IIPT Inc., Sagamihara-shi (JP)

(72) Inventors: Katsumi Tokiguchi, Sagamihara-shi (JP); Izumi Kataoka, Sagamihara-shi (JP); Katsumi Hanazono, Sagamihara-shi (JP); Katsutoshi Tsuchiya, Sagamihara-shi (JP)

(21) Appl. No.: 19/395,360

(22) Filed: Nov. 20, 2025

(30) Foreign Application Priority Data
Dec. 2, 2024 (JP) 2024-209435
Nov. 7, 2025 (JP) 2025-188529

(51) Int. Cl. H01J 37/18; H01J 37/12; H01J 37/24

(52) U.S. Cl. CPC H01J 37/18; H01J 37/12; H01J 37/242; H01J 2237/0041

(57) ABSTRACT

The present invention provides a gas cluster ion beam apparatus capable of achieving flat processing by irradiating a material substrate with a neutral beam. The neutralizing gas introducing device 26 is provided for a vacuum vessel 2. By introducing a neutralizing gas from the neutralizing gas introducing device 26, the gas cluster ion beam 11 traveling along the beamline in the beam transport system BT collides with the neutralizing gas, undergoing dissociation and neutralization to form a high-energy neutral beam 25. Furthermore, a reflecting electrode 28 to which a high voltage equivalent to the acceleration voltage is applied is provided between the electrostatic lens 9b and the material substrate 15.

### TECHNICAL FIELD

The present invention relates to a gas cluster ion beam apparatus, and more particularly to a gas cluster ion beam apparatus suitable for performing advanced surface processing on substrates made of various materials using a gas cluster ion beam.

### BACKGROUND ART

Patent Documents 1 and 2 disclose a conventional gas cluster ion beam apparatus (hereinafter sometimes referred to as a GCIB apparatus) in which a gas cluster beam is ionized by electron impact in an ionizer (an ionization chamber), the generated gas cluster ions are extracted as a beam from the ionizer using an extraction electrode to which a high voltage is applied, and the beam is then transported to an irradiation chamber using an electrostatic lens or the like, and irradiated onto a substrate placed in the irradiation chamber, thereby performing surface processing of the substrate. Surface processing of various material substrates using gas cluster ion beams is not only performed on the substrate itself (surface smoothing processing, etc.), but also on processing to adjust the thickness of a film formed on the substrate (referred to as etching, trimming, etc.). As an application example, the use of gas cluster ion beams for frequency adjustment of surface acoustic wave (SAW) devices and bulk acoustic wave (BAW) devices is known. As device performance improves, extremely flat processing without surface roughness is required for trimming of these devices. The irradiated ion beam is a DC beam with a constant current value.

When a gas cluster beam is ionized by electron impact to obtain gas cluster ions, the majority of the gas cluster ion beam has small amount of singly charged ions in which one electron has been removed from the gas cluster particles. However, in addition to the singly charged ions, multiply charged ions, which are ionized to multiple charge state, are also generated, although the quantity is in small amounts. It is known that the energy of multiply charged ion increases in proportion to the charge state number of multiply charged ion, and therefore the energy of a cluster beam of multiply charged ions increases, resulting on crater-like irradiation marks production on the irradiated substrate (Non-Patent Document 1). Furthermore, when irradiating with a gas cluster ion beam in a high energy range where the acceleration voltage exceeds several tens of kV, even when irradiating with a gas cluster ion beam comprising of single charged ions, similar craters and the like are generated depending on the material, making it difficult to achieve atomic-level smoothing of the substrate surface. In particular, it is known that there is a limit to the flattening of a surface when irradiating a gas cluster ion beam using an inert gas such as Ar, and it is difficult to obtain a surface roughness Ra of 1 nm or less.

To resolve this problem, Patent Document 2 proposes newly providing a high gas pressure region (gas chamber) in the beam transport system of the GCIB apparatus, and passing a gas cluster ion beam through the gas region maintaining at high gas pressure, causing the gas cluster ions to dissociate by collision with gas particles, converting them into a large number of relatively high energy neutral particles, and irradiating the substrate as the neutral particles. In order to achieve sufficient dissociation and neutralization, it is necessary to design so that the product of the gas pressure in this gas region and the length of the gas region have a sufficient value. To maintain the high gas pressure in the gas region, expensive vacuum pump system of high pumping speeds must be used. Furthermore, the gas region must be partitioned by providing walls (so-called gas chamber) with a plurality of apertures at both ends of the beam passage therein. However, since gas leaks from the gas chamber to the beam transport system through multiple apertures, the beam transport system, and the irradiation chamber, in order to prevent the deterioration of the vacuum in each area, it is necessary to further improve the pumping speed of the vacuum pumps in these areas, which necessitates the use of expensive vacuum pumps.

On the other hand, Patent Document 3 proposes a technique in which neutral cluster particles that are not ionized in the gas cluster ionization chamber are utilized as residual gas, and gas cluster ions collide with this residual gas. Thus, the ions are neutralized. When this technique is used, the frequency of collisions between the gas cluster ions and the residual gas particles is lower than when the gas cluster ions are passed through the aforementioned high gas pressure gas region (gas chamber). Therefore, the neutral beam is likely to contain un-neutralized ions. To remove these un-neutralized ions, it has been proposed that two deflection electrodes are installed in the middle of the beam transport system and that high voltage is applied to the electrode. This results in removing the ions by defection. However, in this proposal, although it is not necessary to increase the pumping speed of the pumps in the beam transport system, the provision of two long deflection electrodes induces the new problem of the device becoming longer.

### RELATED ART DOCUMENT

### Patend Documents

Patent Document 1: WO2023/248856 (PCT/JP2023/021620)

Patent Document 2: Japanese Patent No.4805251

Patent Document 3: Japanese Patent Special Publication No. 2014-525813

### Non-Patent Docuent

Non-Patent Document 1: Materials processing by cluster ion beams (Isao Yamada, 2015, CR C Press)

### SUMMARY OF INVENTION

### Technical Problem

In the conventional gas cluster ion beam apparatus disclosed in WO2023/248856 (Patent Document 1), the gas concentration in the beam transport system can be increased by increasing the amount of cluster particles generated in the cluster beam generation chamber. One way to increase the number of cluster particles generated in the cluster beam generation chamber is to increase the pressure of the gas introduced into the cluster beam generation chamber. In this case, the amount of gas (including non-clustered gas molecules) flowing into the cluster beam generation chamber and the beam transport system via the skimmer also increases, causing the gas pressure in the beam transport system to exceed the critical value required for neutralization, which may prevent not only the gas cluster ion beam but also the neutral beam produced by collision and dissociation with the gas from reaching the material substrate. Therefore, there is a limit to how much the gas pressure in the cluster beam generation chamber can be increased. In the case of the apparatus disclosed in Patent Document 3, in which a high-pressure gas region is newly provided between the beam transport system and the material substrate to cause collision and dissociation of the gas cluster ion beam with gas particles, thereby neutralizing the beam, and then etching or trimming is performed to stably obtain an extremely smooth surface (surface roughness Ra<1 nm), it is necessary to set the vacuum pressure (gas concentration) of the beam transport system to a level that allows stable operation for a long period of time. On the other hand, in order to stably operate a beam transport system to which a high voltage is applied in a vacuum with gas inflow, it is necessary to maintain a gas pressure that allows the high voltage to be applied stably. This requires an expensive exhaust system capable of maintaining a high vacuum relative to the amount of gas that flows in. When neutralizing a cluster ion beam, whether the gas pressure in the cluster beam generation chamber is increased or a new high-pressure gas region is provided as in the apparatus disclosed in Patent Document 3, there is a problem in that an expensive exhaust system must be used. Furthermore, when a new high-pressure gas chamber is provided as in the apparatus disclosed in Patent Document 3, there is a problem that the apparatus becomes long.

An object of the present invention is to provide a gas cluster ion beam apparatus that, when irradiating a material substrate with a gas cluster ion beam, achieves extremely flat processing by irradiating the material substrate with a neutral beam.

### BRIEF DESCRIPTION OF DRAWINGS

FIG. 1 is a diagram used to explain the configuration of a gas cluster ion beam apparatus (GCIB apparatus) according to a first embodiment of the present invention.

FIG. 2 is a diagram used to explain a gas cluster ion beam apparatus according to a second embodiment, in which a beam transport system having lens system that does not include an insulator is used as a component of the GCIB apparatus according to the embodiment of FIG. 1.

FIG. 3 is a diagram showing an example of the results obtained by measuring, with a Faraday cup, the change in beam current flowing into the irradiation chamber due to the introduction of gas in the GCIB apparatus according to the embodiment of FIGS. 1 and 2.

FIG. 4 is a diagram used to explain the configuration of a GCIB apparatus previously developed by the inventors and targeted for improvement by the present invention.

### SOLUTION TO PROBLEM

A gas cluster ion beam apparatus of the present invention comprises a gas generator, a cluster beam generation chamber, a skimmer, a first vacuum vessel, an ionization chamber, an acceleration electrode and an extraction electrode, a beam transport system, a second vacuum vessel, a neutralizing gas introducing device. The gas generator generates a high-pressure gas for generating gas cluster. The cluster beam generation chamber has a nozzle in a vacuum. The cluster beam generation chamber generates a neutral gas cluster beam containing clusters formed by gas atoms and/or gas molecules in the gas by injecting the high-pressure gas through the nozzle in the vacuum. The skimmer is provided at an exit of the cluster beam generation chamber and skims a cluster beam from a central region in the neutral gas cluster beam. The first vacuum vessel is communicated with the cluster beam generation chamber. The ionization chamber has a thermal filament and an anode electrode and is set in the first vacuum vessel. In the ionization chamber, thermal electrons generated by the thermal filament are accelerated and collided with the cluster beam. As a result, the cluster beams introduced through the skimmer are ionized and the cluster ions are generated. The acceleration electrode is provided at an outlet of the ionization chamber and the extraction electrode is set downstream of the acceleration electrode, both of which are installed in the first vacuum vessel. The beam transport system in the first vacuum vessel comprises one or more electrostatic lenses to which a positive high voltage is applied from a high voltage power supply. In addition, a permanent magnet system is contained in the beam transport system. The beam transport system is provided downstream of the extraction electrode. The second vacuum vessel is communicated with the first vacuum vessel and forms an irradiation chamber therein. The neutralizing gas introducing device introduces a neutralizing gas into at least one of the first vacuum vessel and the second vacuum vessel to bring an interior of at least one of the first vacuum vessel and the second vacuum vessel to a pressure necessary for neutralizing the cluster ion beam. Wherein the cluster ions are extracted from the ionization chamber as a cluster ion beam by a potential difference between the acceleration electrode and the extraction electrode, and the cluster ion beam transported through the beam transport system is collided and dissociated with the neutralizing gas to generate a neutral beam, which is irradiated onto a material substrate placed in the second vacuum chamber.

According to the present invention, the neutralizing gas introducing device is provided to adjust the pressure inside at least one of the first vacuum vessel and the second vacuum vessel to the pressure required to neutralize the cluster ion beam, making it possible and easy to adjust the gas pressure in the beam transport system, and achieving stable beam transport under condition of a pressure that can sufficiently neutralize the gas cluster ions. Furthermore, the cluster ion beam transported through the beam transport system collides with the neutralizing gas to generate the neutral beam, which is then irradiated onto the material substrate placed in the second vacuum vessel, so that the gas cluster ions can be neutralized efficiently even though a special high gas pressure region is provided.

The neutralizing gas species may be the same type of gas species as the gas for generating gas clusters, a different type of gas species from the gas for generating gas clusters, or a mixed gas of the same type of gas as the gas for generating gas clusters and the different type of gas. For example, when generating Ar gas cluster ions, the gas species flowing from the neutralizing gas introducing device are Ar, N₂, O₂, Kr, etc. When generating NF₃ gas cluster ions, the gases flowing from the neutralizing gas introducing device are Ar, NF₃, N₂, SF₆, He, H₂, etc. In general, the higher the mass number of the gas, the larger the molecular radius, which increases the probability of ion collisions and tends to increase the efficiency of neutralization.

In the present invention, a reflecting electrode to which a positive voltage is applied that reflects un-neutralized ions contained in the neutral beam may be further introduced between the beam transport system and the material substrate, and the neutral beam that passes through the reflecting electrode may be irradiated onto the material substrate. In this manner, the un-neutralized gas cluster ion beam, i.e., the ions in the neutral beam, are reflected by the reflecting electrode, and only the uncharged neutral beam passes through the reflecting electrode and reaches the material substrate. As a result, by removing (reflecting) the un-neutralized ionic components contained in the neutral beam with a reflecting electrode and irradiating the substrate with a neutralized beam containing fewer ionic components, etching or trimming process can be performed to obtain a material substrate with low surface roughness. The length of the reflecting electrode is sufficient to be about the same as that of one cylindrical electrode constituting the Einzel lens within beam transport system, so the beam line does not become long.

The reflecting electrode preferably has a cylindrical structure with a through passage for passing the neutral beam. The cylindrical structure allows for a reflection action that matches the shape of the gas cluster ion beam, which tends to spread into a cylindrical shape, and therefore allows for efficient reflection.

A positive voltage applied to the reflecting electrode is preferably an acceleration voltage (corresponding to the voltage applied to the ionization chamber and the acceleration electrode) that corresponds to the energy of the cluster ion beam. However, even if the positive voltage applied to the reflective electrode is lower than the accelerating voltage, a considerable amount of ion components is removed. Therefore, if a reflective electrode is provided, the surface roughness of the substrate material can be reduced compared to when no reflective electrode is provided. Furthermore, it is preferable that the positive voltage applied to the reflective electrode is variable. For example, it is preferable that the positive voltage applied to the reflective electrode is first applied to the reflective electrode at a voltage lower than the acceleration voltage applied to the acceleration electrode, and then switched to the acceleration voltage or a voltage higher than the acceleration voltage. By varying and switching the positive voltage in this way, high-speed surface processing can be achieved that reduces the surface roughness of the substrate material.

The gas cluster ion beam apparatus according to the present invention, further may comprise a calorimeter heated by irradiation of the neutral beam within the second vacuum vessel and a controller that determines an irradiation amount of the neutral beam from an integral value of a temperature of the calorimeter and heating time duration and that determines a gas flow rate from the neutralizing gas introducing device and/or an amount of current flowing to the thermal filament or a voltage value applied between the thermal filament and the anode rod according to the irradiation amount. In this way, the extraction beam current and gas flow rate of the cluster ion beam extracted from the ionization chamber can be adjusted in accordance with changes in the integrated value signal from the controller, which has the advantage of allowing the amount of neutral beam irradiation onto the material substrate to be accurately adjusted to the desired value. The beam current of the cluster ion beam extracted from the ionization chamber is specifically adjusted by adjusting the output voltage of an ionization power supply, a current of a filament heating power supply, and the like.

It is preferable that the one or more electrostatic lenses in the beam transport system does not include an insulator. When the neutralizing gas is introduced into at least one of the first vacuum vessel and the second vacuum vessel from the neutralizing gas introducing device, high voltage electric breakdown generally tends to occur in the high voltage application section. The abnormal breakdown may occur at the electrical insulator of the one or more electrostatic lenses electrodes in the beam transport system. As the one or more electrostatic lenses, a plurality of Einzel lenses can be used, each of which is a set of lenses made up of three cylindrical electrodes fixed together via insulators. A high voltage comparable to the energy of gas cluster ions is applied to the electrode of the electrostatic lens. Therefore, if the gas flow rate from the neutralization gas introducing device increases and the gas pressure becomes higher than necessary, abnormal electric breakdown discharge (creeping discharge) is likely to occur along the surface of the insulator that holds the electrode of the electrostatic lens. For this reason, it is preferable to use one or more electrostatic lenses having a structure that does not include an insulator. By using a structure that does not include insulator in the beam transport system, abnormal electric breakdown due to creeping discharge along the insulator surface is drastically reduced even if the vacuum gas pressure along the beamline increases. As a result, the cluster ions are dissociated by collision between the cluster ion beam and the neutralizing gas, and converted into neutral particles, making it possible to irradiate the material substrate with a stable neutral beam.

### DETAILED DESCRIPTION OF THE EMBODIMENTS

In order that the invention may be more clearly understood one or more embodiments thereof will now be described, by way of example only, with reference to the accompanying drawings, of which:

The present invention will be described in detail below with reference to the accompanying drawings. Before describing the preferred embodiments of the present invention, the configuration of a gas cluster ion beam (GCIB) apparatus previously proposed by the inventors, which is the subject of the present invention, will be described, and then the preferred embodiments of the present invention will be described.

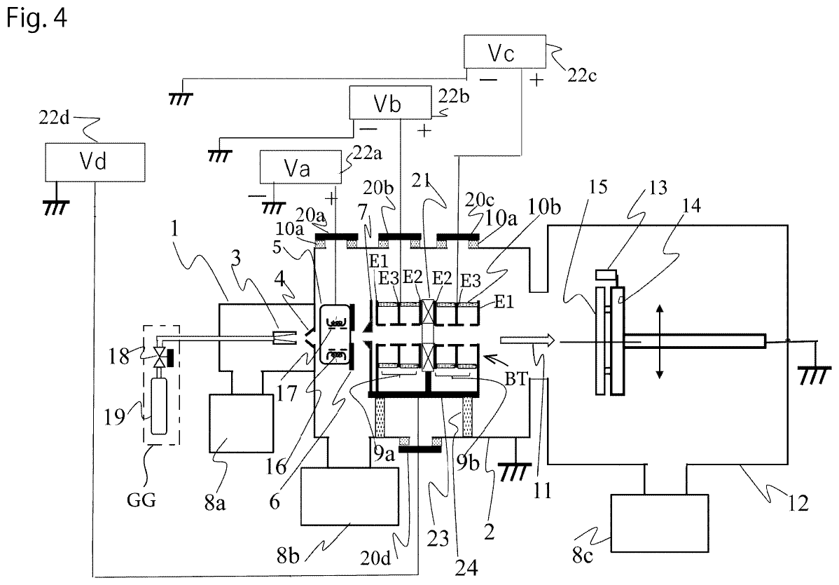

FIG. 4 is a diagram showing the configuration of the GCIB apparatus previously proposed by the inventors and which is the subject of improvement of the present invention. In FIG. 4, reference numerals are used as follows. 1 denotes a cluster beam generation chamber, 2 denotes a first vacuum vessel, 3 denotes a nozzle, 4 denotes a skimmer, 5 denotes an ionization chamber of an ionizer, 6 denotes an acceleration electrode, 7 denotes an extraction electrode, 8a, 8b and 8c denote vacuum exhaust pumps, 9a and 9b denote a first electrostatic lens and a second electrostatic lens, 12 denotes a second vacuum vessel. 13 denotes a Faraday cup, 14 denotes a stage for an irradiated substrate, 15 denotes a material substrate, 16 denotes a tungsten thermal filament, 17 denotes an anode rod, 18 denotes a pressure reducing cock, 19 denotes a high-pressure gas cylinder, 21 denotes a permanent magnet type magnet, and 22a, 22b and 22c denote first high voltage power supply, second high voltage power supply and third high voltage power supply. The gas generator GG is composed of the pressure reducing cock 18 and the high-pressure-gas cylinder 19. The beam transport system BT is composed of the electrostatic lenses 9a and 9b and the permanent magnet type magnet 21.

In the conventional GCIB apparatus illustrated in FIG. 4, when the gas which is introduced from the high-pressure gas cylinder 19 to the nozzle 3 is ejected from the nozzle 3, condensation of atoms and molecules occurs due to adiabatic expansion so that a neutral gas cluster beam is formed. Thereafter, only the neutral gas cluster beam that is high-density and is positioned at the center portion of the neutral gas cluster beam is skimmed as a neutral gas cluster beam by the skimmer 4 and then the neutral gas cluster beam is introduced into an ionization chamber 5 of the ionizer. In the ionization chamber 5, thermal electrons generated from the tungsten thermal filament 16 are accelerated to several hundreds of eV, which is corresponding to the DC voltage applied to the anode rod 17, and collide with the neutral cluster beam causing ionization. Therefore, the neutral cluster beam is efficiently ionized. The DC voltage power supply that applies voltage to the thermal filament 16 and the anode rod 17 is not shown in FIG. 4.

Next, a voltage of several tens of kV (Va in the figure) is applied to the acceleration electrode 6 from the first high voltage power supply 22a through the high voltage introduction flange 20a, the cluster ions are extracted from the outlet of the ionization chamber 5 of the ionizer as the gas cluster ion beam 11 due to the voltage difference (=the electric field strength) between the acceleration electrode 6 to which a high voltage is applied and the extraction electrode 7 at ground potential. Then, the ion beam is transported to the material substrate 15 positioned in the second vacuum vessel 12 as an irradiation chamber vacuum vessel using the first electrostatic lens 9a and the second electrostatic lens 9b referred to Einzel lenses which are included in the beam transport system BT. The first electrostatic lens 9a and the second electrostatic lens 9b are formed by fixing three cylindrical metal electrodes to each other via electrical insulators 10b, and each of the first and second electrostatic lenses 9a and 9b has cylindrical electrodes E1 and E2 at both ends. A positive high voltage, bias voltage Vd, is applied to the cylindrical electrodes E1 and E2 from a high voltage power supply 22d as a bias power supply via a high voltage introduction flange 20d. Positive high voltages Vb and Vc are respectively applied to cylindrical central electrodes E3 of the first electrostatic lens 9a and the second electrostatic lens 9b from the second high voltage power supply 22b and the third high voltage power supply 22c. By adjusting the voltages Vb and Vc applied to the central electrodes E3 in the first and second electrostatic lenses 9a and 9b, it is possible to control the beam shape and transport the beam with little current loss. Note that the high voltage introduction flanges 20a, 20b and 20c are fixed to the first vacuum vessel 2 via an insulator 10a. The extraction electrode 7 and the cylindrical electrodes E1 and E2 at both ends of the first and second electrostatic lenses 9a and 9b are at the same potential Vd.

The permanent magnet type magnet 21 is mounted between the first electrostatic lens 9a and the second electrostatic lens 9b in the beam transport system BT. The magnet 21 deflects and removes monoatomic or monomolecular singly charged ions (hereinafter referred to monomer ions) included in the gas cluster ion beam 11, so as to prevent the monomer ions from reaching onto the material substrate 15. Monomer ions penetrate deeply into the material substrate upon irradiation and generate radiation defects deep within the surface, so the monomer ions are removed using a magnet.

The material substrate 15 is positioned in a state that the material substrate 15 is attached to the stage 14 in the second vacuum vessel 12. Then the irradiation of the gas cluster ion beam 11 is carried out onto the material substrate 15. The Faraday cup 13 is attached to the stage 14 and serves to measure the current value of the gas cluster ion beam 11. The Faraday cup current which is measured by the Faraday cup 13 is measured by an ammeter (not illustrated) which is placed outside of the second vacuum vessel 12 through an electric cable. When the current value is measured, the stage 14 for the material substrate 15 moves in the direction of the arrow in the figure, the Faraday cup 13 moves to a position where the axis of the Faraday cup 13 and the gas cluster ion beam 11 coincide, and the measurement of the current value of the gas cluster ion beam 11 is carried out.

In FIG. 4, the energy (eV) of the gas cluster ion beam 11 that is irradiated onto the material substrate 15 at ground potential is the value of the voltage (Va, several kV to several tens of kV) which is applied to the ionization chamber 5 of the ionizer (the acceleration electrode 6) multiplied by the ions charged number (usually singly charged, that is 1). However, when the gas cluster ion beam 11 is irradiated onto the material substrate 15, atoms or molecules that constitute the gas cluster ion beam 11 are broken apart, spread along the surface and etch the material substrate 15, causing so-called lateral sputtering phenomenon. The average energy per one atom or one molecule that is formed by dissociation of the gas cluster ion beam 11 is given by dividing the above-mentioned energy of the gas cluster ion beam by the cluster size (number), and is distributed in the range of several eV to several tens of eV (several V to several tens of V in voltage conversion). Compared to a general-purpose ion beam processing apparatus that performs surface processing by accelerating singly charged ions to several kV, this GCIB apparatus can provide surface processing that causes less damage to the surface structure of the material substrate 15. Furthermore, substrate processing (etching, etc.) using the beam of a conventional ion beam processing machine mainly involves processing in the direction perpendicular to the surface. In contrast, processing using the gas cluster ion beam utilizes the so-called lateral sputtering effect, in which dissociated atoms/molecules spread laterally along the surface to process it, as mentioned above, and has the advantage of being able to achieve excellent trimming processing for surface flattening.

Furthermore, by appropriately selecting the gas species, beam irradiation energy, and processing conditions (irradiation angle and irradiation amount), processing with small surface roughness (Ra value indicating surface roughness of a few nm or less) can be achieved. When the above-mentioned magnet is used, the singly charged cluster beam is deflected to a small extent and reaches the material substrate. However, electron impact ionization in the ionization chamber typically produces not only singly charged ions but also small amounts of doubly or more highly ionized ions. Because the energy of these ions increases in proportion to their charge state number, they cannot be deflected and removed using magnets designed for removing monomer ions. Because multiply-charged cluster ion beams have high energy, they leave crater-like irradiation marks on substrates, causing surface roughness increase. Therefore, it is difficult to achieve irradiation processing with a surface roughness Ra of 1 nm or less. Furthermore, size of magnet for removing multiply-charged ions must be extremely long and require high magnetic field strength, making it practically impossible to obtain a general-purpose irradiation apparatus.

In the conventional apparatus of FIG. 4, when the material substrate is made of an insulating material such as SiO2, alumina, or diamond, the material substrate becomes charged-up by the irradiated ions, causing the beam to diverge and making it difficult for the irradiated ion beam to efficiently reach the material substrate. Furthermore, If the thickness of the insulating material substrate is thin, there is a possibility that the dielectric breakdown through the thin material substrate may occur due to charge-up. Therefore, in conventional apparatuses shown in FIG. 4, to prevent charging up, an electron source (not shown in FIG. 4) is placed midway along the beam line, and electrons from the electron source are simultaneously irradiated onto the material substrate together with the gas cluster ion beam irradiation, thereby preventing charge-up. Another method is to provide a separate high gas pressure region midway through the beam transport. When the gas cluster ions pass through this region, the cluster ion beams are converted into neutral beams by collision with neutral gases. In this collision process, this collision induced the dissociation of cluster ion beams, and neutral particles having energy lower than the incident ion energy. Then, the converted high energy neutral beams irradiate the material substrate (see Patent Document 2).

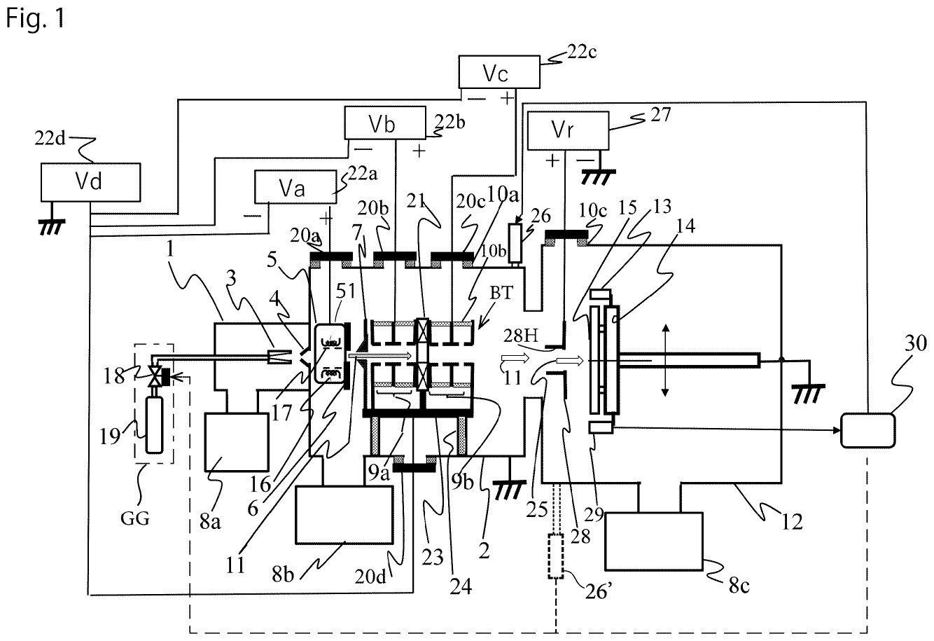

FIG. 1 is a diagram showing the configuration of a GCIB apparatus according to an embodiment of the present invention, which overcomes the problems of the conventional apparatus shown in FIG. 4. In this embodiment, a neutralizing gas introducing device 26 is provided for the first vacuum vessel 2 to introduce a neutralizing gas to create a pressure rise inside the first vacuum vessel 2 necessary to neutralize the cluster ion beam, compared with the conventional GCIB apparatus shown in FIG. 4. In addition, in this embodiment, a cylindrical reflecting electrode 28 to which a high voltage equivalent to the acceleration voltage is applied is newly provided between the Einzel lens 9b at the final stage of the beam transport system BT and the material substrate 15, which reflects un-neutralized ions contained in the neutral beam.

In this embodiment, similar to the conventional gas cluster ion beam apparatus of FIG. 1, in the cluster beam generating chamber 1, high-pressure gas is injected through a nozzle 3 placed in a vacuum, thereby adiabatically expanding the gas atoms and/or gas molecules, thereby generating a neutral gas cluster beam containing clusters formed by the gas atoms and/or gas molecules of the gas. From the neutral gas cluster beam generated in the cluster beam generating chamber 1, a cluster beam in the central region of the neutral gas cluster beam is selected and extracted by a skimmer 4, and the extracted cluster beam is introduced into an ionization chamber 5. The ionization chamber 5 is at the same potential as the acceleration electrode 6, and a positive high voltage equal to the voltage Va of the high voltage power supply 22a is applied to the ionization chamber 5. The ionization chamber 5 is provided with a thermal filament 16 that generates thermal electrons for ionization and an anode rod 17 to which an electron acceleration voltage Vi is applied that accelerates the thermal electrons for ionization. Cluster ions are generated by causing thermal electrons accelerated by the electron acceleration voltage Vi to collide with and ionize a cluster beam introduced into the conductive housing 51 of the ionization chamber 5 through the skimmer 4. Since the thermal electrons are accelerated and move in the direction of the central axis of the housing 51, ionization of neutral gas clusters occurs along the central axis region of the housing 51. The gas cluster ions are extracted from the ionization chamber 5 by the voltage difference between the acceleration electrode 6 and the extraction electrode 7. The energy of the gas cluster ions is the acceleration voltage Va multiplied by the electron charge (1.6×10⁻¹⁹ coulombs) (expressed in eV).

The beam transport system BT (9a, 9b, 21) extracts cluster ions from the ionization chamber 5 as a gas cluster ion beam 11 by the potential difference between an acceleration electrode 6 provided at the exit of the ionization chamber 5 and to which a positive high voltage is applied, and an extraction electrode 7 provided downstream of the acceleration electrode 6. Next, the beam diameter of the gas cluster ion beam 11 is adjusted through electrostatic lenses 9a and 9b to which a positive high voltage is applied from a high voltage power supply. Usually, the cluster ion beam with a reduced diameter is irradiated onto the material substrate 15 placed in a second vacuum vessel 12.

In the first embodiment of FIG. 1, a neutralizing gas introducing device 26 is provided for a part of the first vacuum vessel 2. Similar to the gas generator GG, the neutralizing gas introducing device 26 is composed of a pressure reducing cock and a high-pressure gas cylinder. The pressure reducing cock adjusts the gas flow rate into the first vacuum vessel 2 under the control of a controller 30, which will be described later. In this embodiment, the neutralizing gas introducing device 26 is arranged so that the neutralizing gas flowing into the first vacuum vessel 2 is directed toward the beam line of the gas cluster ion beam 11 passing between the beam transport system BT and the reflecting electrode 28. By injecting neutralizing gas from this neutralizing gas introducing device 26 into the first vacuum vessel 2, the gas cluster ion beam 11 moving along the beam line in the beam transport system BT (9a, 9b, 21) collides with the introduced gas particles, undergoing dissociation and neutralization, and a high-energy (several tens of eV or more) neutral beam 25 is generated.

As shown by the dashed line in FIG. 1, the neutralizing gas introducing device 26′ may also be provided for the second vacuum vessel 12. When the neutralizing gas introducing device 26′ is provided for the second vacuum vessel 12, it is also preferable to position the neutralizing gas introducing device 26′ so that the neutralizing gas is directed toward the beam line of the gas cluster ion beam 11 passing between the beam transport system BT and the reflecting electrode 28.

As mentioned earlier, in this embodiment, the reflecting electrode 28 having a tubular (or cylindrical) structure with a through passage 28H to which a high voltage equivalent to the acceleration voltage is applied is provided between the second electrostatic lens 9b and the material substrate 15. The reflecting electrode 28 reflects and removes un-neutralized ions contained in the neutral beam 25. A positive high voltage Vr is applied to the reflecting electrode 28 from a high voltage power supply 27. Un-neutralized ions have a maximum energy equivalent to the acceleration voltage, and the reflecting electrode 28 to which a voltage equivalent to the acceleration voltage is applied acts as a potential barrier, preventing un-neutralized ions from passing through it. Therefore, the neutral beam 25 irradiated onto the material substrate 15 is only a high-speed neutral beam that does not contain any ions. Therefore, by irradiating the material substrate 15 with such a neutral beam, an extremely smooth processed surface can be obtained.

Next, as a result of dissociation caused by collision between the introduced gas introduced from the neutralizing gas introducing device 26 and the cluster ion beam, ions corresponding to a voltage generally lower than the acceleration voltage are also generated concomitantly. By adjusting the voltage applied to the reflecting electrode 28 within the range from 0 V to the acceleration voltage, the part of incidentally generated ions (dissociated ions) can exceed the voltage barrier of the reflecting electrode 28 according to their energy, and can pass through the reflecting electrode 28. However, the energy of these ions is lower (several kV to less than the acceleration voltage) than the energy of the gas cluster ion beam 11 that enters the material substrate 15 to be irradiated from the beam transport system BT in the absence of a neutralizing gas, so the surface roughness of the material substrate 15 caused by irradiation can be made much smaller. At the same time, the surface roughness of the material substrate 15 can also be repaired by the large amount of neutral beams (having an energy of several tens to several hundreds of eV) irradiated onto the material substrate 15. When comparing the processing speed (amount of material etched per unit time) when etching a material substrate, the processing speed when irradiated only with gas cluster ion beam 11 having relatively high energy is much greater than the processing speed when using a neutral beam containing slow ions generated by collision dissociation. Therefore, by adjusting the voltage of the reflecting electrode 28 as follows, high-speed smoothing processing without surface roughness can be achieved. That is, in the etching process in which gas is introduced from the neutralizing gas introducing device 26, a voltage lower than the acceleration voltage is first applied to the reflecting electrode 28 to perform etching with high-energy gas cluster ion beam 11. Thereafter, by applying a voltage equal to or higher than the acceleration voltage to the reflecting electrode 28, irradiation with the gas cluster ion beam 11 is switched to irradiation with the neutral beam 25 alone. In this way, high speed, smooth surface processing without surface roughness can be achieved.

When the neutralizing gas is introduced from the neutralizing gas introducing device 26 into the first vacuum vessel 2 that has been evacuated, and the gas cluster ions are dissociated and neutralized by collision of the gas cluster ion beam 11 with the neutralizing gas, if the flow rate of the neutralizing gas increases and the vacuum gas pressure in the beam transport system BT (9a, 9b, 21) becomes higher than necessary, abnormal discharges (corona discharges, creeping discharges) are likely to occur at various points in the beam transport system BT where high voltages are applied. Of course, if the flow rate of the neutralizing gas is properly controlled, the abnormal discharge will not occur.

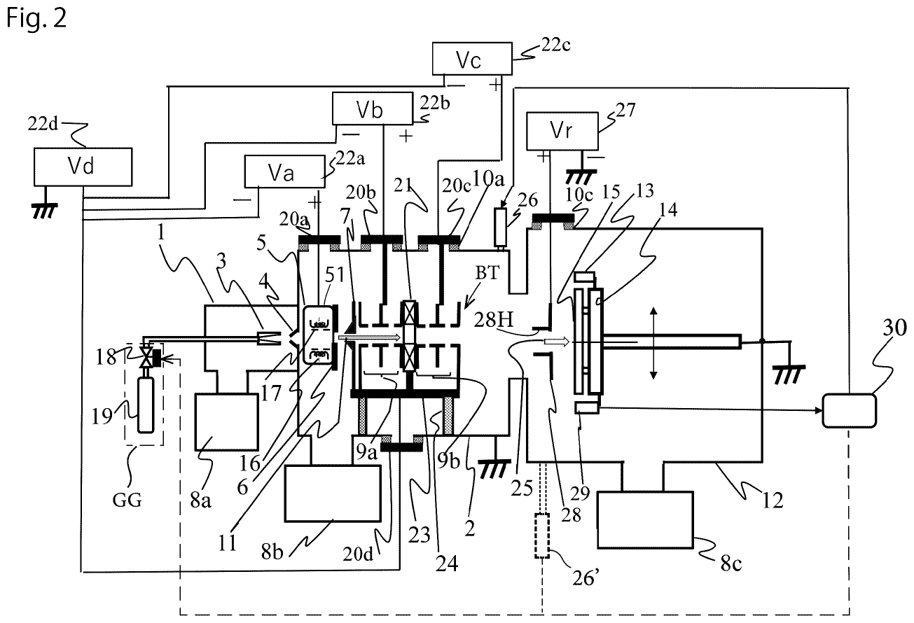

FIG. 2 shows the configuration of the gas cluster ion beam apparatus according to a second embodiment of the present invention, which employs a simple structure for actively preventing such discharge, in which no insulator (the insulators indicated by reference numeral 10b in FIGS. 1 and 4) is included between the cylindrical electrodes of the first and second electrostatic lenses 9a and 9b. That is, the second embodiment provides the gas cluster ion beam apparatus that performs neutral conversion of the gas cluster ion beam with little abnormal discharge in the beam transport system BT. In the second embodiment shown in FIG. 2, the insulators for the first and second electrostatic lenses 9a and 9b included in the beam transport system BT are removed, and their central cylindrical electrodes are directly connected to the flanges 20b and 20c. This configuration was proposed by the inventors in Patent Document 3. In the embodiment of FIG. 2, the neutralizing gas introducing device 26 is also provided for the first vacuum vessel 2 incorporating the beam transport system BT, and a cylindrical reflecting electrode 28 is further provided between the exit of the beam transport system BT (the end of the electrostatic lens 9b) and the material substrate 15, and a positive high voltage Vr is applied to the reflecting electrode 28 from the high-voltage power supply 27.

The configuration of the conventional gas cluster ion beam apparatus shown in FIG. 4 alone does not allow for direct electrical measurement of the irradiation amount (proportional to the amount of substrate etching) of the neutral beam 25 obtained by dissociation due to collision between the cluster ion beam and gas particles. In order to perform irradiation with good reproducibility using an energetic neutral beam, it is necessary to appropriately measure the amount of neutral beam flowing into the material substrate and control the irradiation time and irradiation conditions (gas inflow amount, etc.) based on the measurement results.

Therefore, in the embodiment shown in FIGS. 1 and 2, a calorimeter 29 is provided to measure the amount of heat generated by the irradiation of the neutral beam 25, in addition to the Faraday cup 13 that measures the ion beam quantity. Like the Faraday cup 13, the calorimeter 29 is attached to the stage 14 and measures the amount of heat generated by the irradiation of the neutral beam 25. When performing measurements using the calorimeter 29, the stage 14 is moved to a position where the axes of the calorimeter 29 and the neutral beam 25 are aligned.

The calorimeter 29 may be a metal or semiconductor substrate with a small heat capacity to which a thermocouple is attached. The calorimeter 29 is a device that measures the amount of heat absorbed and emitted by the material substance, and several types of thermocouple-type calorimeters are currently commercially available. The temperature of the calorimeter 29 rises as the neutral beam irradiation begins and settles at a constant temperature. If the amount of neutral beam is constant, the temperature of the calorimeter 29 will remain constant. The amount of neutral beam varies depending on the amount of gas cluster ion beam 11 extracted from the ionization chamber 5.

The amount of neutral beam irradiation is determined by the integrated value (integral value) obtained by integrating the temperature and the time it is maintained. Therefore, the current value of the gas cluster ion beam 11 extracted from the ionization chamber 5 is controlled so as to achieve a predetermined integrated value. The integration controls are performed by the controller 30. In the embodiments shown in FIG. 1 and FIG. 2, based on a control signal from the controller 30, the current value of the extracted gas cluster ion beam and the flow rate of the gas introduced from the neutralizing gas introducing device 26 are adjusted in accordance with changes in the integrated value. The current of the extracted gas cluster ion beam is adjusted by adjusting the voltage (referred to as the ionization voltage) applied to the anode rod 17 in the ionization chamber 5 and the filament current in the ionization chamber 5. In actual irradiation work, as shown by the arrows in FIG. 1, the substrate is mechanically scanned multiple times during irradiation work, so the neutral beam 25 inevitably enters the calorimeter 29 during multiple scans. Therefore, the integration process is performed based on the temperature rise value measured by the calorimeter 29 when the neutral beam 25 enters the calorimeter 29 during the multiple scans, and the irradiation is adjusted based on the result of the integration process.

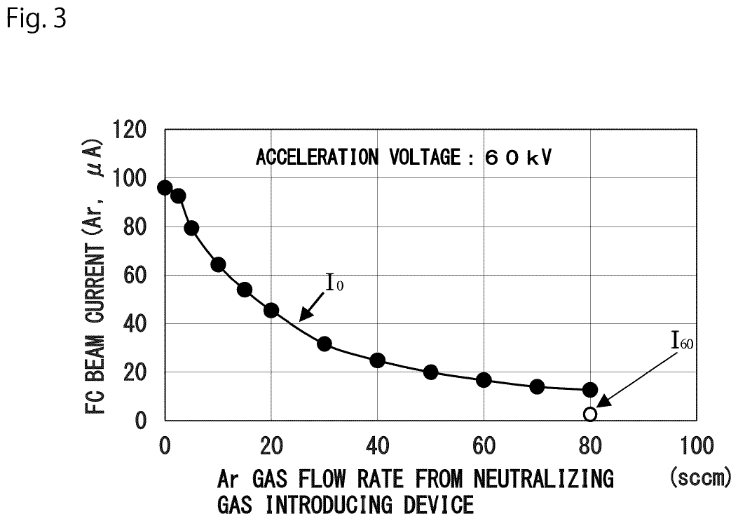

FIG. 3 shows an example of the relationship between the gas flow rate from neutralizing gas introducing device and the gas cluster ion beam current (FC beam current) measured by the Faraday cup 13 when the gas is introduced using the neutralizing gas introducing device 26. In FIG. 3, when the acceleration voltage was 60 kV, the black circles represent the FC beam current I₀ when the voltage applied to the reflecting electrode 28 was set to 0 V, and the white circle represents the FC beam current I₆₀ when the accelerating voltage was 60 kV and a voltage of 60 kV was applied to the reflecting electrode 28 at a gas flow rate of 80 sccm (standard cubic centimeters per minute). The curve in FIG. 3 shows that when the voltage Vr of the reflecting electrode 28 is set to 0 V, the collisional dissociation of the gas cluster ion beam progresses as the gas flow rate increases, the gas cluster ion beam current gradually decreases, and the gas cluster ion beam is converted into a neutral beam. The difference between the beam current at a gas flow rate of 0 sccm and the beam current at each gas flow rate corresponds to the amount of current of the neutral beam. However, even if the gas flow rate is increased, the FC beam current cannot be reduced to completely zero because the proportion of the beams that cause collisions among the gas cluster ion beams extracted from the ionization chamber 5 increases exponentially with the distance from the extraction electrode 7. If the gas cluster ion beam is transported a long enough distance, the FC beam current can be reduced to zero.

In the first embodiment of FIG. 1, when the gas flow rate was further increased from the state shown in FIG. 3, abnormal discharges (creeping discharges) frequently occurred in the insulators 10b for fixing the electrodes in the electrostatic lenses 9a and 9b of the beam transport system BT, making stable irradiation difficult. In addition, when the gas flow rate is 80 sccm or less, the frequency of abnormal discharge decreases with decreasing gas flow rate. As described above, in FIG. 3, when the gas flow rate is 80 sccm and the voltage applied to the reflecting electrode 28 is 60 kV, the FC beam current is close to 0 as indicated by the white circles. When the voltage applied to the reflecting electrode 28 was further increased, the FC beam current became zero, and the un-neutralized ion beam component became zero. When the gas flow rate is 80 sccm and the voltage of the reflecting electrode is 60 kV or less, the FC beam current transitions from the white circle to the black circle in accordance with the voltage of the reflecting electrode. At other flow rates, if the voltage of the reflecting electrode is set to 60 kV, the FC beam current also becomes close to zero at those flow rates. Therefore, at a voltage of less than 60 kV, an irradiation beam containing a mixture of ion beams and neutral beams is obtained. By including the ion beam in the neutral beam, a reasonably high trimming speed can be obtained. In addition, the presence of the neutral beam reduces the roughness of the sample surface, resulting in a flat surface that is improved compared to irradiation with the ion beam alone. FIG. 3 shows the results when Ar ions were used as the gas cluster ions and Ar gas was used as the neutralization gas, but similar results were also obtained with combinations of other gas species (N₂, O₂, Kr, CO₂, SF₆, NF₃). The results were also confirmed with mixed gases of the aforementioned gases.

Next, silicon wafers with a SiO₂ film were irradiated with the beams for the same fixed period of time under the conditions that the voltage applied to the reflecting electrode 28 was zero and a neutralizing gas was introduced at a constant flow rate (black circles in FIG. 3), and under the conditions that a voltage of 60 kV, which is equal to the acceleration voltage, was applied to the reflecting electrode 28 at a gas flow rate of 80 sccm (white circle in FIG. 3). As a result, etching of SiO₂ was confirmed in both cases. The amount of etching was greater under the conditions of the black circles, but it was found that the surface roughness becomes flatness of Ra<1 nm as the conditions approach the condition of the white circle.

In the embodiment shown in FIGS. 1 and 2, the gas used to generate gas clusters is Ar (argon), N₂ (nitrogen), CO₂ (carbon dioxide), O₂ (oxygen), Kr (krypton), NF₃ (nitrogen trifluoride), SF₆ (sulfur hexafluoride), or a mixed gas obtained by diluting these gases with He, N₂, or the like. The neutralizing gas (a gas suitable for causing collisional dissociation of gas cluster ions) introduced from the neutralizing gas introducing device 26 into the first vacuum vessel 2 or the second vacuum vessel 12 may be a gas for generating clusters or a combination of different gases. The gas to be used is selected appropriately depending on the efficiency of neutralization and the chemical reactivity of the neutral beam.

In the above two embodiments, the conditions for irradiating the material substrate with the neutral beam are described. However, if the voltage applied to the reflective electrode is set equal to or lower than the acceleration voltage, a neutral beam containing ions can be irradiated. In this case, the trimming speed can be made faster than when irradiating the neutral beam containing no ions. However, by selecting an appropriate acceleration voltage, it has been found that a smooth surface can be obtained while maintaining an appropriate trimming speed. It has also been found that the surface smoothness improves as the voltage applied to the reflecting electrode approaches the acceleration voltage.

While the preferred embodiments of the invention have been described with a certain degree of particularity with reference to the drawings, obvious modifications and variations are possible in light of the above teachings. It is therefore to be understood that within the scope of the appended claims, the invention may be practiced other than as specifically described.

### Industrial Application

According to the present invention, the neutralizing gas introducing device is provided to adjust the pressure inside at least one of the first vacuum vessel and the second vacuum vessel to the pressure required to neutralize the cluster ion beam, making it possible and easy to adjust the gas pressure in the beam transport system, and achieving stable beam transport under a pressure that can sufficiently neutralize the gas cluster ions. Furthermore, the cluster ion beam transported through the beam transport system is collided with the neutralizing gas particles to generate the neutral beam, which is then irradiated onto the material substrate placed in the second vacuum vessel, so that the gas cluster ions can be neutralized efficiently without providing a special high gas pressure region.

What is claimed is:

1. A gas cluster ion beam apparatus comprising:
a gas generator for generating high-pressure gas for generating gas cluster,
a cluster beam generation chamber having a nozzle in a vacuum that generates a neutral gas cluster beam containing clusters formed by gas atoms and/or gas molecules in the gas by injecting the high-pressure gas through the nozzle in the vacuum,
a skimmer provided at an exit of the cluster beam generation chamber that skims a cluster beam from a central region in the neutral gas cluster beam,
a first vacuum vessel communicating with the cluster beam generating chamber,
an ionization chamber having a thermal filament and an anode electrode and provided in the first vacuum vessel, in which thermal electrons generated by the thermal filament are accelerated and collided with the cluster beam to ionize the cluster beam introduced through the skimmer and generate cluster ions,
an acceleration electrode provided at an outlet of the ionization chamber and an extraction electrode provided downstream of the acceleration electrode, both of which are disposed in the first vacuum vessel,
a beam transport system disposed in the first vacuum vessel that comprises one or more electrostatic lenses to which a positive high voltage is applied from a high voltage power supply and a permanent magnet type magnet,
a second vacuum vessel communicating with the first vacuum vessel and forming an irradiation chamber therein, and
a neutralizing gas introducing device for introducing a neutralizing gas into at least one of the first vacuum vessel and the second vacuum vessel to bring an interior of at least one of the first vacuum vessel and the second vacuum vessel to a pressure necessary for neutralizing the cluster ion beam;
wherein the cluster ions are extracted from the ionization chamber as a cluster ion beam by a potential difference between the acceleration electrode and the extraction electrode, and wherein the cluster ion beam transported through the beam transport system is collided with the neutralizing gas to generate a neutral beam, which is irradiated onto a material substrate placed in the second vacuum chamber.

2. The gas cluster ion beam apparatus according to claim 1,
wherein a reflecting electrode to which a positive voltage is applied that reflects unneutralized ions contained in the neutral beam is disposed between the beam transport system and the material substrate, and
wherein the neutral beam that passes through the reflecting electrode is directed onto the material substrate.

3. The gas cluster ion beam apparatus according to claim 2,
wherein the reflecting electrode has a cylindrical structure provided with a through passage for passing the neutral beam.

4. The gas cluster ion beam apparatus according to claim 2,
wherein the positive voltage applied to the reflecting electrode is variable.

5. The gas cluster ion beam apparatus according to claim 4,
wherein the positive voltage applied to the reflecting electrode is switched to the acceleration voltage or a voltage equal to or higher than the acceleration voltage after applying a voltage lower than the acceleration voltage applied to the accelerating electrode to the reflecting electrode.

6. The gas cluster ion beam apparatus according to claim 1,
wherein the neutralizing gas is a gas of the same type as the gas used to generate the gas cluster beam, a gas of a different type from the gas used to generate the gas cluster beam, or a mixed gas of the gas of the same type as the gas used to generate the gas cluster beam and the gas of the different type.

7. The gas cluster ion beam apparatus according to claim 1, further comprising:
a calorimeter heated by irradiation of the neutral beam within the second vacuum vessel, and
a controller that determines an irradiation amount of the neutral beam from an integral value of a temperature of the calorimeter and heating time duration and that determines a gas flow rate from the neutralizing gas introducing device and/or an amount of current flowing to the thermal filament or a voltage value applied between the thermal filament and the anode rod according to the irradiation amount.

8. The gas cluster ion beam apparatus according to claim 1,
wherein the one of electrostatic lenses in the beam transport system does not include an insulator.
